(19) United States
(12) Patent Application Publication
(10) Pub. No.: US 2026/0191113 A1
(43) Pub. Date: Jul. 2, 2026

(54) STACKED THREE-DIMENSIONAL MEMORY DEVICE USING HYBRID BONDING

(71) Applicant: HaiSemi Inc., Pheonix, AZ (US)

(72) Inventor: Shengmin WEN, Phoenix, AZ (US)

(21) Appl. No.: 19/427,779

(22) Filed: Dec. 19, 2025

Related U.S. Application Data
(60) Provisional application No. 63/739,668, filed on Dec. 29, 2024.

(51) Int. Cl. H10W 90/28; H10B 80/00; H10W 20/43; H10W 80/00; H10W 90/00

(52) U.S. Cl. CPC H10W 90/28; H10B 80/00; H10W 20/43; H10W 80/312; H10W 80/327; H10W 90/722; H10W 90/792

(57) ABSTRACT

A three-dimensional dynamic random access memory (DRAM) device includes a first DRAM die and a second DRAM die bonded through hybrid bonding between their respective bonding layers. The first DRAM die has a bonding layer with inter-die bonding pads surrounded by dielectric materials. The second DRAM die has a bonding layer with exterior pads and pairs of electrically connected die pads, including inter-die bonding pads and exterior pads, also surrounded by dielectric materials. The first DRAM die is connected externally through the exterior pads of the second DRAM die when the inter-die bonding pads of the first and second DRAM dies are coupled, enabling stacked memory access.

### CROSS-REFERENCE TO RELATED APPLICATIONS

This application claims priority to U.S. Patent Application No. 63/739,668, filed on Dec. 29, 2024, which is incorporated by reference herein in its entirety.

### TECHNICAL FIELD

This disclosure relates to semiconductor integrated circuit (IC) devices, and more particularly to a three dimensional dynamic random access memory (DRAM) device.

### BACKGROUND

Electronic devices (e.g., computers, laptops, tablets, copiers, digital cameras, smart phones, and the like) often employ integrated circuits (ICs). These integrated circuits are typically implemented as IC chips packaged in packages. The IC chips may include processors, programmable logic circuits, application specific ICs, memory, and/or any of various other suitable circuit types.

Memory is commonly incorporated into various electronic devices. ICs within the electronic devices can communicate with the memory. A number of technologies have been created for different types of memory. High bandwidth memory (HBM) is one such technology. HBM provides low latency, high bandwidth access to memory by an IC. HBM is a three dimensional DRAM device through packaging of multiple identical DRAM dies with through silicon via (TSV) process, providing a plurality of data input/output channels in parallel through TSV interconnections. Such TSV interconnections increase the manufacturing costs with the yield.

### SUMMARY

Embodiments relate to a three-dimensional (3D) dynamic random access memory (DRAM) device that includes a first DRAM die and a second DRAM die. The first DRAM die has a first bonding layer including first inter-die bonding pads surrounded by first dielectric materials. The second DRAM die has a second bonding layer bonded to the first bonding layer of the first DRAM die through hybrid bonding. The second bonding layer includes first exterior pads, second exterior pads, second inter-die bonding pads and second dielectric materials. The second inter-die bonding pads couple the first inter-die bonding pads of the first DRAM die to the first exterior pads to enable external coupling of the first DRAM.

In one or more embodiments, the first inter-die pads of the first DRAM are configured to transmit or receive one or more of data input/output signal, data mask signal, data strobe signal, clock signal, clock enable signal, data clock signal, command signal, address signal, chip select signal, on-die termination control signal, calibration signal, power, ground, or reset signal.

In one or more embodiments, the second exterior pads of the second DRAM are configured to transmit or receive one or more of data input/output signal, data mask signal, data strobe signal, clock signal, clock enable signal, data clock signal, command signal, address signal, chip select signal, on-die termination control signal, calibration signal, power, ground, or reset signal.

In one or more embodiments, each of the second inter-die bonding pads is coupled to each of the first exterior pads.

In one or more embodiments, each of the first inter-die bonding pads of the first DRAM is coupled to each of the second inter-die bonding pads of the second DRAM.

In one or more embodiments, the first DRAM die and the second DRAM die share a same circuit configuration.

In one or more embodiments, the first DRAM die and the second DRAM die have differences in at least one of a circuit configuration, silicon nodes, or manufacturing locations.

In one or more embodiments, the inter-die bonding pads of the first DRAM die and the second DRAM die have the same size and the same pitch such that the first inter-die bonding pads and the second inter-die bonding pads align for the hybrid bonding.

In one or more embodiments, each of the second inter-die bonding pads is coupled to each of the first exterior pads by a metal layer of a back end of line (BEOL) structure of the second DRAM die.

In one or more embodiments, the first exterior pads are arranged along a first line, and the second exterior pads are arranged along a second line adjacent to the first line.

In one or more embodiments, the first exterior pads and the second exterior pads are externally connected through plating flip chip copper (Cu) bumps on the first exterior pads and the second exterior pads.

In one or more embodiments, the first exterior pads and the second exterior pads are externally connected through wire bond connecting wires made of gold (Au), copper (Cu), aluminum (Al), or metal alloys.

In one or more embodiments, the hybrid bonding is a wafer-to-wafer hybrid bonding, a die-to-wafer hybrid bonding or a die-to-die hybrid bonding.

### BRIEF DESCRIPTION OF THE DRAWINGS

FIGS. 1A through 1D illustrate an example high band width or high density DRAM unit.

FIGS. 2A and 2B are diagrams illustrating example designs of two DRAM dies for a three-dimensional integrated circuit (3D IC) construction, according to one embodiment.

FIGS. 2C through 2F are diagrams illustrating example designs of two DRAM dies to form a 3D IC, according to one embodiment.

FIGS. 2G and 2H are partial cross-sectional views depicting the hybrid bonding method, according to one embodiment.

FIGS. 3A through 3C are diagrams illustrating a 3D IC design, according to another embodiment.

FIGS. 4A and 4B are block diagrams illustrating die designs for 3D IC architecture design, according to other embodiments.

FIG. 4C is a diagram illustrating a 3D IC design with added channel and band width, according to an embodiment.

FIG. 4D is a diagram illustrating a 3D IC design with added memory channel capacity, according an embodiment.

FIG. 5 is a flowchart illustrating a method of the 3D IC construction process, according to one embodiment.

FIGS. 6A through 6C are diagrams illustrating a 3D IC schematic with the corresponding designs, according to an embodiment.

FIGS. 7A through 7C are diagrams illustrating a 3D IC schematic with the corresponding designs, according to another embodiment.

FIGS. 8A and 8B are diagrams illustrating a 3D IC and its application, according to one embodiment.

The figures depict embodiments of the present disclosure for purposes of illustration only.

### DETAILED DESCRIPTION

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments. In the drawings, reference numerals in the drawings denote elements.

Some examples described herein relate to electronic devices that are configured to implement high band width memory architecture or used as building block to construct HBM or optionally per JDEC standard definition. In some examples, higher capacity and increased depth of HBM memory can be achieved by implementing inter-die bonding. In some examples, higher bandwidth can be achieved by using a configurable die pad design.

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the claimed subject matter or as a limitation on the scope of the claimed subject matter. In addition, an illustrated example need not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

It will also be understood that, although the terms first, second, etc. may be used herein to describe various elements, these elements should not be limited by these terms. These terms are only used to distinguish one element from another. For example, a first DRAM die could be termed a second DRAM die, and, similarly, a second DRAM die could be termed a first DRAM die, without departing from the scope of the present invention. The first memory die and the second DRAM die are both DRAM dies, but they are not the same DRAM die.

As used in the description of the invention and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, operations, elements, and/or components, but do not preclude the presence or addition of one or more other features, operations, elements, components, and/or groups thereof.

Unless specifically disclosed herein as having a different meaning, the term “substantially the same value” means differing in value by no more than ten percent.

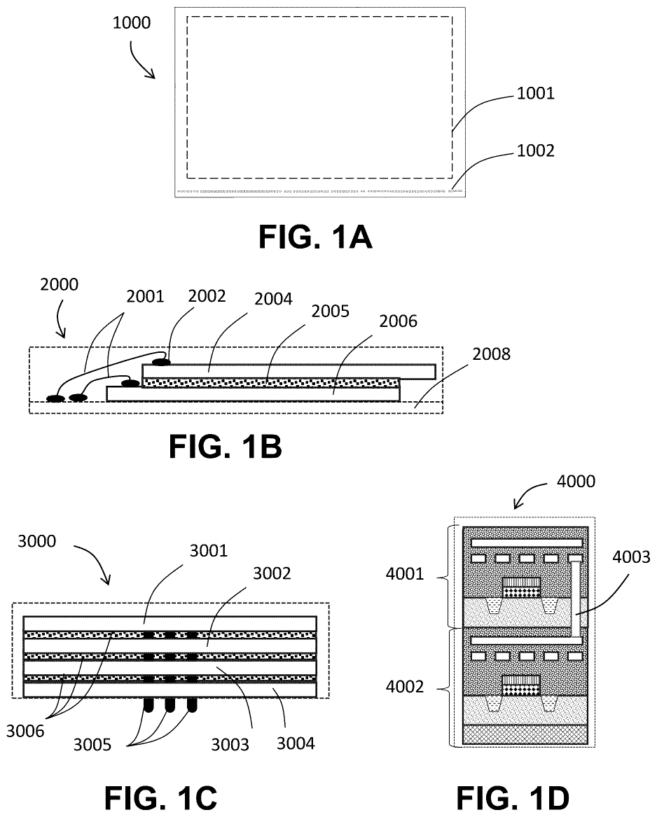

FIGS. 1A through 1D illustrate an example a high band width or high density DRAM unit. FIG. 1A shows a standard DRAM die 1000 that has an interior memory cell area 1001 and a plurality of exterior pads 1002 for external connection. These external connections include the DRAM die signals such as data input/output, data mask, data strobe, clock, clock enable, data clock, command, address, chip select, on-die termination control, calibration, power, ground, and reset.

FIG. 1B shows an exemplary multiple DRAM dies package 2000 that uses wire bond connection 2001 to substrate 2008 through the DRAM exterior die pads 2002 of the two DRAM dies 2004 and 2006. The two DRAM dies are stacked with adhesives 2005, one sitting on top of the other. The package may be molded, have a large form factor, and low thermal conductivity. The benefit of such method is low cost.

FIG. 1C shows an exemplary multiple DRAM dies package 3000 that uses TSVs, Cu bumps, and solder connections 3005. This may be JEDEC HBM1 that uses 3D stack of a total of four same DRAM dies 3001, 3002, 3003 and 3004. The insulation layer 3006 may become an obstacle to thermal dissipation. This type of package is associated with a high cost, a low yield, and a low thermal performance.

FIG. 1D shows an exemplary 3D DRAM die 4000 that has device layers 4001 and 4002 stack and joined together, connected by TSVs 4003. Such devices are generally difficult to manufacture, limiting wide adoption.

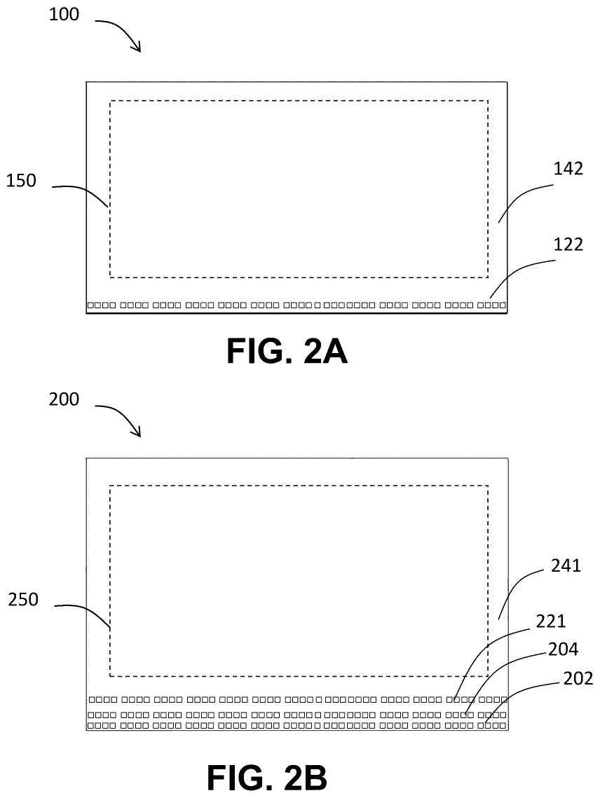

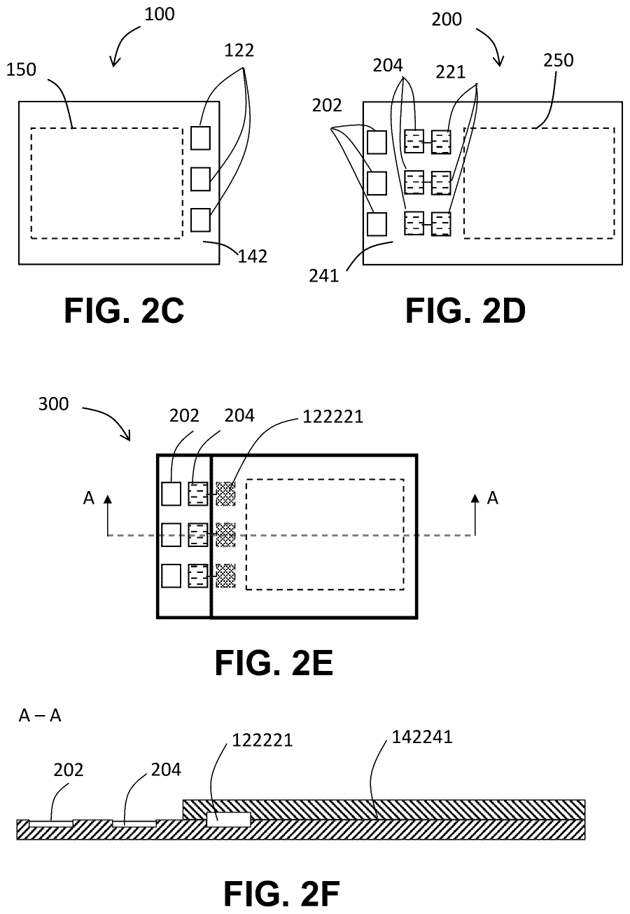

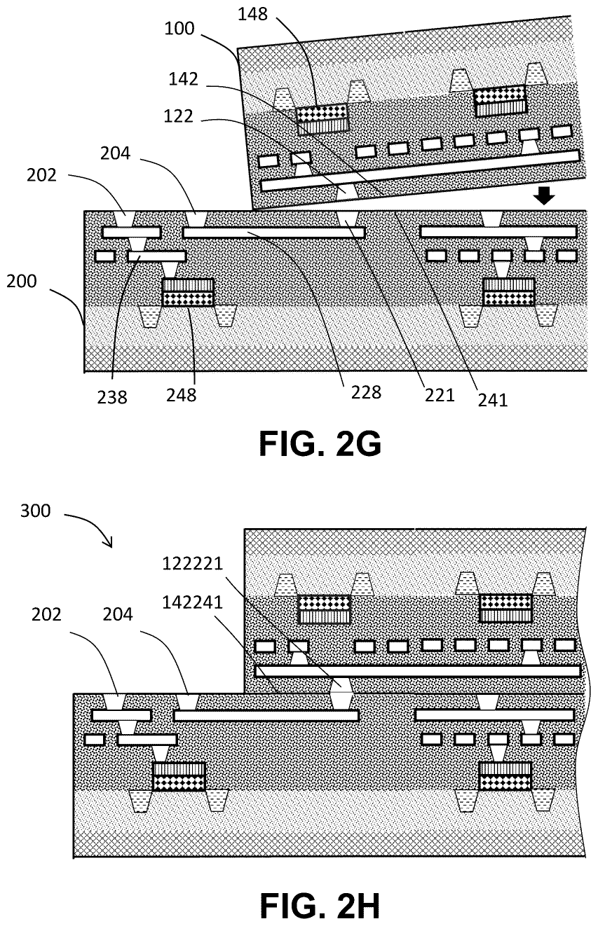

The following drawings are all related to embodiments of a three dimensional dynamic random access memory (DRAM) and the design and a fabrication method. FIGS. 2A and 2B are diagrams illustrating the designs of two DRAM dies for a 3D IC construction, according to one embodiment.

FIG. 2A illustrates a first die 100 having an interior memory cell area 150, (exaggerated in scale to show that a larger area is occupied by the memory cells), a surface bonding layer comprising a plurality of inter-die pads 122 and surrounded by dielectric material 142. These inter-die pads 122 provide the external access to the first die 100 of its basic signals including, but not limited to, data input/output signal, data mask signal, data strobe signal, clock signal, clock enable signal, data clock signal, command signal, address signal, chip select signal, on-die termination control signal, calibration signal, power, ground, and reset signal.

FIG. 2B illustrates a second die 200, having substantially the same size interior memory cell area 250 as the first die 100, a surface bonding layer having a plurality of exterior die pads 202, a plurality of die pad pairs 221 and 204, and surrounded by dielectric material 241. The exterior die pads 202 provide the external access to the second die 200 of its signals, including, but not limited to, data input/output signal, data mask signal, data strobe signal, clock signal, clock enable signal, data clock signal, command signal, address signal, chip select signal, on-die termination control signal, calibration signal, power, ground, and reset signal. Die pad 221 is an inter-die pad while die pad 204 is an exterior die pad. Die pad 221 and die pad 204 are electrically connected or shorted at the back end of line (BEOL) metal layer level of the second die. Inter-die pads 221 of the second die 200 are to be bonded to inter-die pads 122 of the first die 100, establishing direct electrical connection between inter-die pads 122 of the first die to the exterior pads 204 of the second die such that die pads 204 function as the exterior connection pads of the first die 100. The number of die pads 221 of the second die 200 may be equal to or greater than the number of die pads 122 of the first die 100, such that for every die pad 122 there is at least one die pad 221 or more than one die pads 221 for the die pad 122 to be bonded thereto.

Now turning to FIG. 2C, a first die 100 is covered by a first bonding layer including a plurality of inter-die pads 122 and the surrounding dielectric materials 142 where the memory cell area 150 is at the interior of the die and shown here for visualizing its location. FIG. 2D is a diagram better illustrating a second die 200 covered by a second bonding layer including a plurality of inter-die pads 221, a plurality of die pad pairs 221 and 204, and the surrounding dielectric materials 241 where the memory cell area 250 is at the interior of the die and shown here for the purpose of visualizing its location.

FIG. 2E is a diagram illustrating a 3D IC die 300 that is fabricated by hybrid bonding the first die 100 and the second die 200 through the bonding of their bonding layers. An inter-die pad 122 of the first die 100 is aligned to and bonded with an inter-die pad 221 of the second die 200, forming one solid connection 122221 that electrically connects each inter-die pad 122 of the first die 100 to a corresponding exterior die pad 204 of the second die 200. Exterior die pads 204 of the second die 200 become the exterior die pads of the first die 100. After the hybrid bonding, the dielectric materials 142 of the first die and the dielectric materials 241 of the second die are also bonded together, providing solid bonding strength of these two dies. Exterior die pads 202 and 204 are the exterior pads for the 3D IC die 300. FIG. 2F is a cross-sectional view taken along line A-A of FIG. 2E and shows exterior pads 202, 204 and connection 122221.

FIG. 2G is a partial cross-sectional view depicting the structure and the hybrid bonding method, according to one embodiment. FIG. 2G illustrates that the die pad pair 221 and 204 is connected at the top level redistribution metal layer 228 in the BEOL layers of the second die 200. The pair may not be connected to any functional part of the second die 200, including the transistors 248, die pads 202, to provide independent external connection of the first die 100. However, depending on the 3D IC architecture design of die 300, the pair may be electrically connected at any level of BEOL metal layers 238 or transistors 248.

Hybrid bonding process includes three major steps: the first step is to prepare the bonding layers of die 100 and die 200 by chemical mechanical planarization (CMP) and activation thereafter; the second steps is to align the activated bonding layers of the two dies face-to-face, with inter-pads 122 of the first die 100 carefully aligned to inter-pads 221 by a precise placement mechanism of the hybrid bonding machine and bond together with high precision, hybrid bonding machine in general having a three sigma placement tolerance of less than 1.0 micrometer or 1.0 micron; and the third and final step is to anneal at high temperature such that the inter-die bonding pads 122 and 221 are bonded together to form solid metal connection as well as the dielectric materials 142 and 241 are bonded together seamlessly to achieve a strong bonding between the two bonding layers. FIG. 2H is a partial cross-sectional view of the 3D IC 300 after hybrid bonding with solid electric connection 122221 and dielectric materials bonding are 142241, according to one embodiment. As shown in FIG. 2H, exterior pads 202 and 204 are ready for external connections.

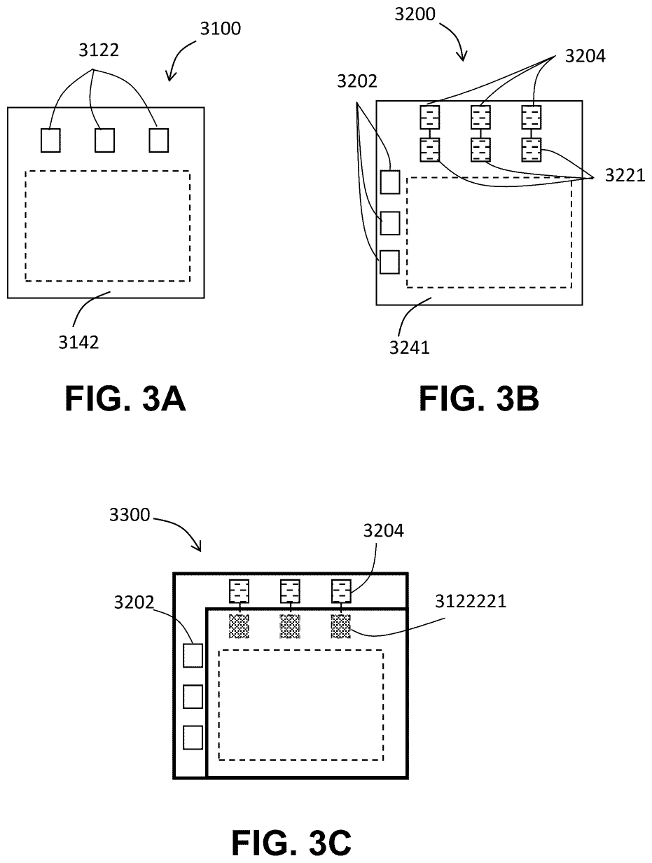

FIGS. 3A through 3C are diagrams illustrating a 3D IC design, according to another embodiment. FIG. 3A shows that the first die 3100 has inter-die pads 3122 placed on the north side to match the exterior connecting pads 3204 on the north side of the second die 3200 to achieve a final north side external connection. FIG. 3B shows the die pads layout design on the bonding layer of the second die 3200. FIG. 3C shows the final 3D IC 3300 with its exterior pads 3202 and 3204 placement as well as the connections 3122221. Such placement may bring, among other benefits, integration benefits, especially for mobile devices such as mobile phones or wearables where space is tight.

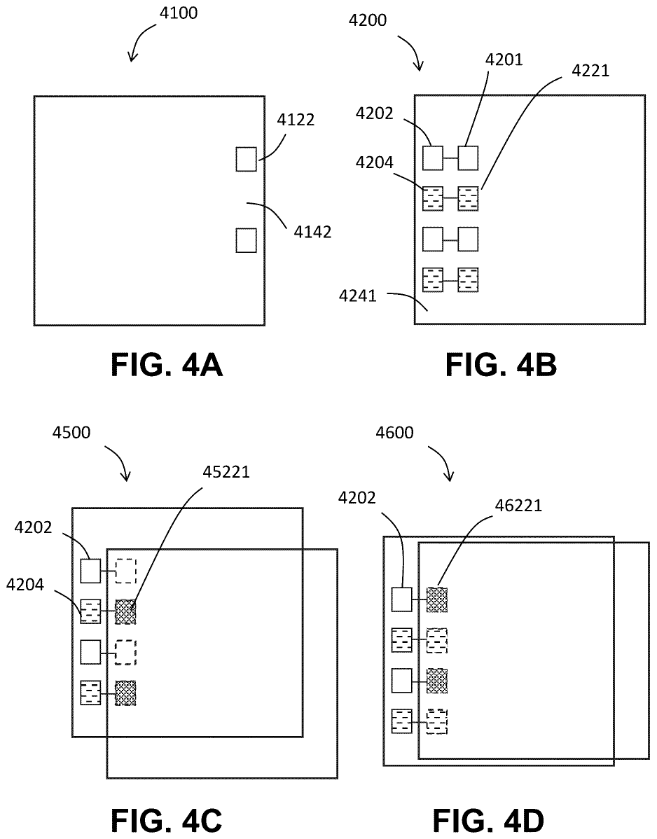

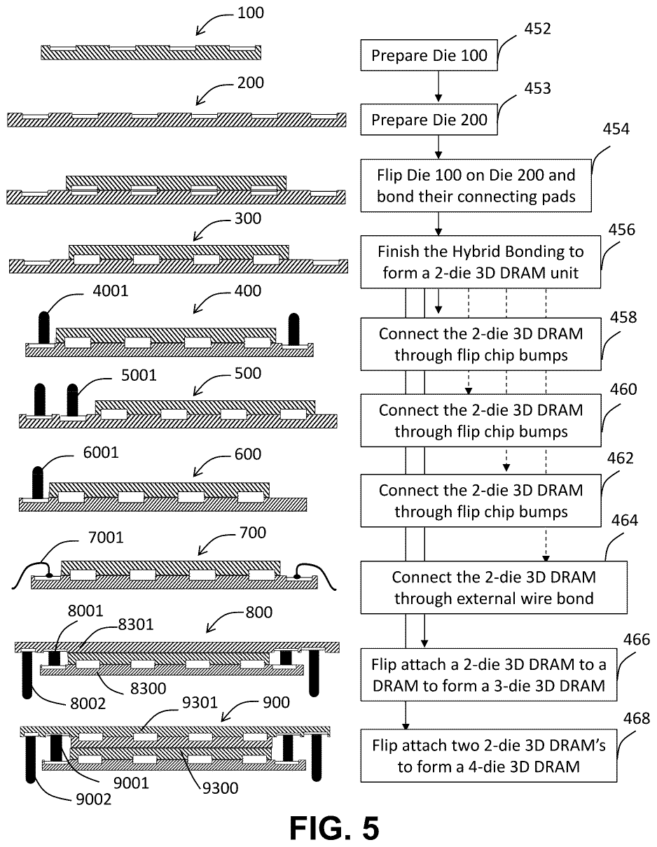

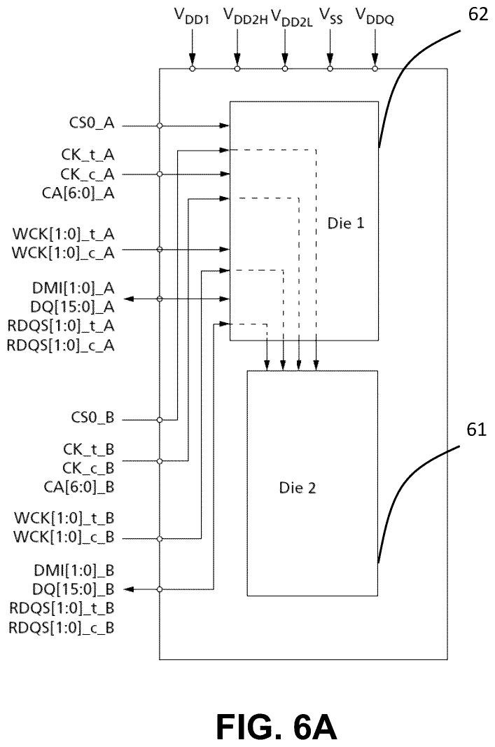

FIGS. 4A and 4B are diagrams illustrating two die designs for more flexible 3D IC design, according to other embodiments. FIG. 4A shows the design for the first die 4100, with inter-die pads 4122 having a larger pitch. FIG. 4B shows the design for the second die 4200, with exterior die pads 4202 designed as a die pad pair with an added inter-die pad 4201 and the 4204/4221 die pad pair pads moved to in-between the exterior die pads 4202/4201 pair.

FIG. 4C is a block diagram illustrating a 3D IC die 4500 architecture design, using the first die 4100 of FIG. 4A and the second die 4200 of FIG. 4B, aligning the inter-die pads 4122 of the first die 4100 and the inter-die pads 4221 of the second die, creating a 3D IC die 4500 that has wider band width as much as the addition of the bandwidth of the first die 4100 and the second die 4200. For example, if both the first die 4100 and the second die 4200 have 512 input/output data pins each the 3D IC 4500 will have a total of 1024 data pins according to JEDEC HBM 3 standard I/O specification.

FIG. 4D is a diagrams illustrating a 3D IC die 4600 architecture design, using the first die 4100 of FIG. 4A and the second die 4200 of FIG. 4B, aligning the inter-die pads 4122 of the first die 4100 and the inter-die pads 4201 of the second die, creating a 3D IC die 4600 that has memory capacity per each data pin as much as the addition of the per data pin capacity of the first die 4100 and the second die 4200. For example, if both the first die 4100 and the second die 4200 have 64 Mb capacity per pin the 3D IC 4600 will have a total of 128 Mb memory capacity per data pin.

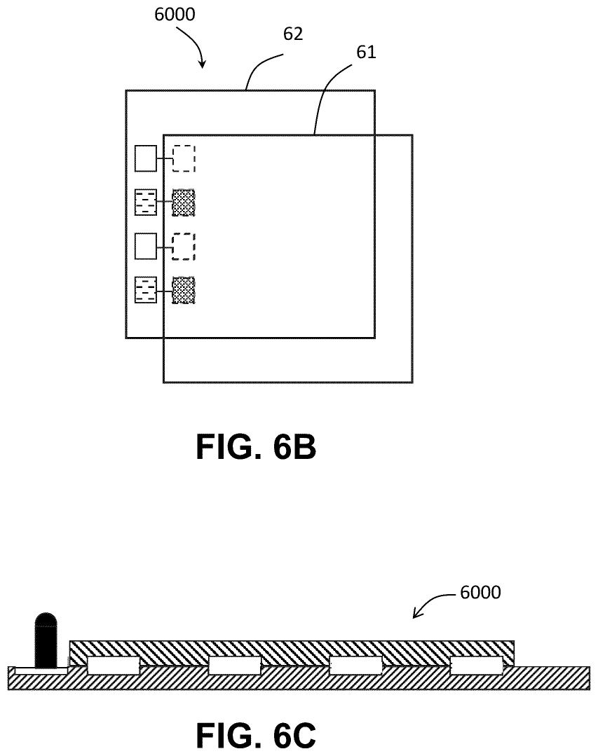

FIG. 5 is a flowchart illustrating exemplary method of fabricating a 3D IC for various configurations, e.g., chip 300, for various embodiments of the present invention. A first die 100 of a certain design is provided and its bonding layer is prepared 452. A second die 200 of a certain design that is substantially similar to the first die 100 is provided and its bonding layer is prepared 453. Then, the first die is flipped 454 on the second die 200, and their connection pads are bonded.

The first die 100 and the second die 200 are hybrid bonded 456 together face-to-face, with their inter-die pads aligned and dielectric materials surface aligned. An anneal process may be applied to achieve uniform and finish 456 reliable hybrid bonding between the inter-die pads and between the dielectric surfaces, forming a 3D IC device 300. With the device 300 as a building block, multiple next steps can be selected with flexibility to form different external connection types and/or architectures. For example, a two-die monolithic 3D IC may be configured as a die 400 by external connecting 458 copper (Cu) bumps 4001 on a plurality of die sides like the architecture shown in FIG. 3C. Alternatively, a die 500 may be externally connected 460 via Cu bumps 5001 on one side as shown in FIG. 2E. In another embodiment, a die 600 may be externally connected 462 to Cu bumps 6001 placed on one side similar to the architecture shown in FIG. 4C and/or FIG. 4D. Further, a die 700 may be connected 464 via external wire bond connection 7001 on a plurality of sides as shown in FIG. 3C. In yet another exemplary embodiment, a 3-die integrated IC 800 can be fabricated by flip attaching 466 a two-die 3D device 8300 and a single die 8301 through copper bump flip chip connection 8001 where the integrated IC 800 are external connection of copper bumps 8002 on a plurality of sides. In yet another exemplary embodiment, two two-die 3D DRAMs 9300, 9301 may be flip attached 468 to form a 4-die integrated IC 900 with the two two-die 3D devices 9300, 9301 through copper bump flip chip connection 9001, where the integrated IC 900 may be configured with external connection of copper bumps 9002 on a plurality of sides.

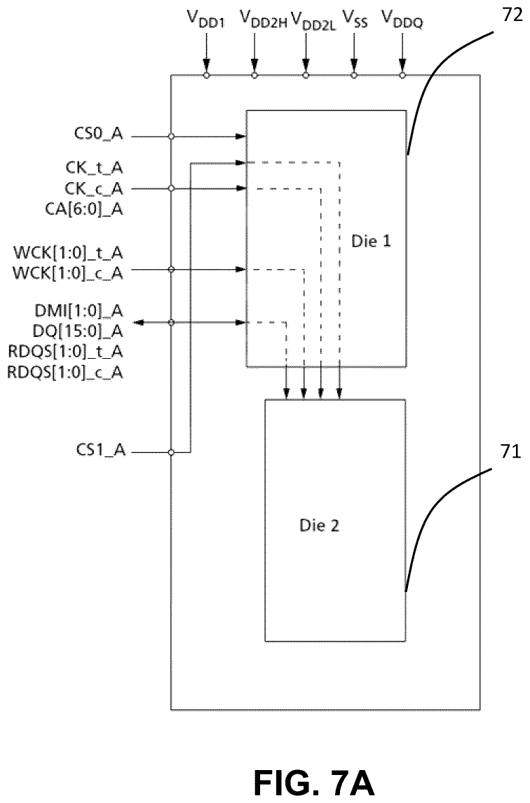

FIG. 6A is a circuit schematic of a two-die 3D IC with die 61 and die 62, according to one embodiment. FIG. 6B illustrates a design to achieve the 3D IC 6000, according to one embodiment. FIG. 6C illustrates a cross-sectional view of the embodiment 3D IC 6000 with a copper bump flip chip external connection, according to one embodiment. In FIG. 6C, the while elongated boxes represent inter-die bonding pads of dies 61, 62 bonded together.

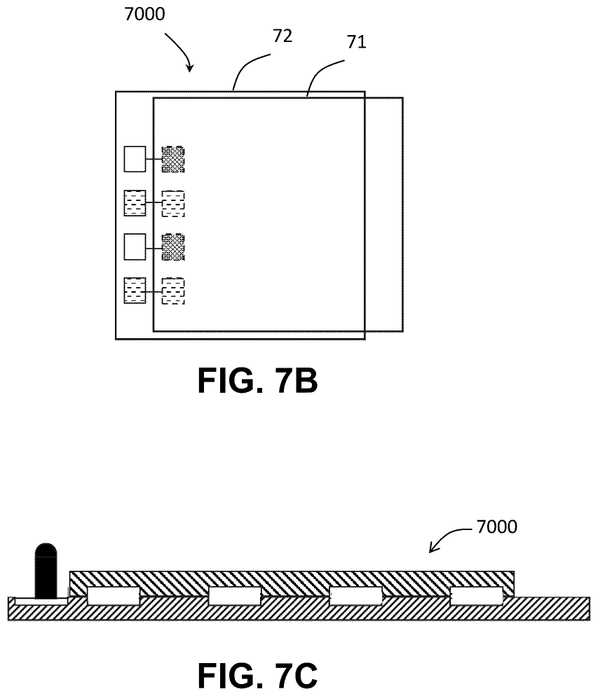

FIG. 7A is a circuit schematic of a two-die 3D IC with die 71 and die 72, according to one embodiment. FIG. 7B shows the diagram illustrating the designs to achieve the 3D IC 7000, according to one embodiment. FIG. 7C illustrates a cross-sectional view of the embodiment 3D IC 7000 with a copper bump flip chip external connection, according to one embodiment.

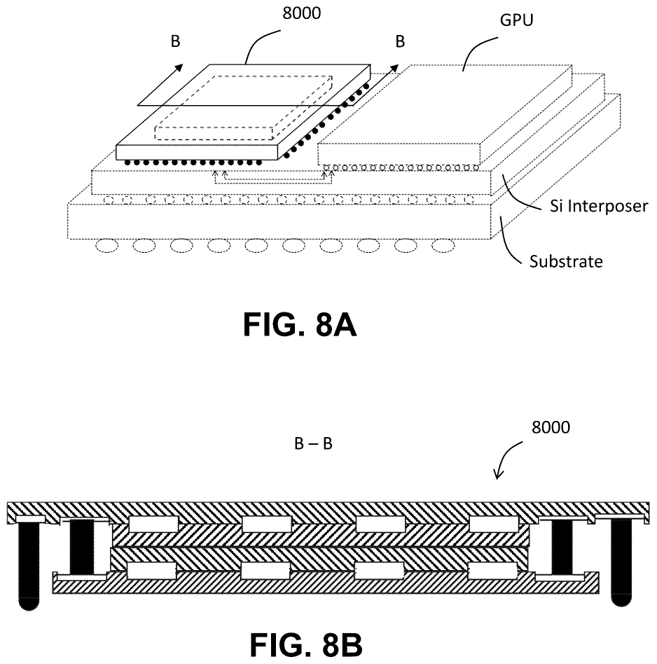

FIG. 8A is a perspective view illustrating a 3D IC HBM 8000 according to one embodiment placed on a Si interposer, sitting close to a GPU. FIG. 8B is a cross-sectional view taken along line B-B of FIG. 8B, according to one embodiment.

Upon reading this disclosure, those of skill in the art will appreciate still additional alternative ways of structuring and fabricating memory devices. Thus, while particular embodiments and applications have been illustrated and described, it is to be understood that the invention is not limited to the precise construction and components disclosed herein and that various modifications, changes and variations which will be apparent to those skilled in the art may be made in the arrangement, operation and details of the method and apparatus disclosed herein without departing from the spirit and scope of the present disclosure.

What is claimed is:

1. A three-dimensional (3D) dynamic random access memory (DRAM) device comprising:
a first DRAM die having a first bonding layer comprising first of inter-die bonding pads surrounded by first dielectric materials; and
a second DRAM die having a second bonding layer bonded to the first bonding layer of the first DRAM die through hybrid bonding, the second bonding layer comprising first exterior pads, second exterior pads, second inter-die bonding pads and second dielectric materials, the second inter-die bonding pads coupling the first inter-die bonding pads of the first DRAM die to the first exterior pads to enable external coupling of the first DRAM.

2. The 3D DRAM device of claim 1, wherein the first inter-die pads of the first DRAM are configured to transmit or receive one or more of data input/output signal, data mask signal, data strobe signal, clock signal, clock enable signal, data clock signal, command signal, address signal, chip select signal, on-die termination control signal, calibration signal, power, ground, or reset signal.

3. The 3D DRAM device of claim 1, wherein the second exterior pads of the second DRAM are configured to transmit or receive one or more of data input/output signal, data mask signal, data strobe signal, clock signal, clock enable signal, data clock signal, command signal, address signal, chip select signal, on-die termination control signal, calibration signal, power, ground, or reset signal.

4. The 3D DRAM device of claim 1, wherein each of the second inter-die bonding pads is coupled to each of the first exterior pads.

5. The 3D DRAM device of claim 4, wherein each of the first inter-die bonding pads of the first DRAM is coupled to each of the second inter-die bonding pads of the second DRAM.

6. The 3D DRAM device of claim 1, wherein the first DRAM die and the second DRAM die share a same circuit configuration.

7. The 3D DRAM device of claim 1, wherein the first DRAM die and the second DRAM die have differences in at least one of a circuit configuration, silicon nodes, or manufacturing locations.

8. The 3D DRAM device of claim 1, wherein the inter-die bonding pads of the first DRAM die and the second DRAM die have the same size and the same pitch such that the first inter-die bonding pads and the second inter-die bonding pads align for the hybrid bonding.

9. The 3D DRAM device of claim 4, wherein each of the second inter-die bonding pads is coupled to each of the first exterior pads is connected by a metal layer of a back end of line (BEOL) structure of the second DRAM die.

10. The 3D DRAM device of claim 1, wherein the first exterior pads are arranged along a first line, and the second exterior pads are arranged along a second line adjacent to the first line.

11. The 3D DRAM device of claim 1, wherein the first exterior pads and the second exterior pads are externally connected through plating flip chip copper (Cu) bumps on the first exterior pads and the second exterior pads.

12. The 3D DRAM device of claim 1, wherein the first exterior pads and the second exterior pads are externally connected through wire bond connecting wires made of gold (Au), copper (Cu), aluminum (Al), or metal alloys.

13. The 3D DRAM device of claim 1, wherein the hybrid bonding is a wafer-to-wafer hybrid bonding.

14. The 3D DRAM device of claim 1, wherein the hybrid bonding is a die-to-wafer hybrid bonding.

15. The 3D DRAM device of claim 1, wherein the hybrid bonding is a die-to-die hybrid bonding.

16. A three-dimensional (3D) dynamic random access memory (DRAM) device, comprising:
a first DRAM die having a first bonding layer comprising first of inter-die bonding pads surrounded by first dielectric materials; and
a second DRAM, having a second bonding layer comprising first exterior pads, second exterior pads, second inter-die bonding pads, and second dielectric materials, the second bonding layer bonded to the first bonding layer using copper bump flip chip bonding, each of the second inter-die bonding pads coupled to each of the first exterior pads, the first DRAM die connected externally through the first exterior pads.

17. The 3D DRAM device of claim 16, wherein the copper bump flip chip bonding is a wafer-to-wafer bonding.

18. The 3D DRAM device of claim 16, wherein the copper bump flip chip bonding is a die-to-wafer bonding.
